(19) United States
(12) Patent Application Publication
(10) Pub. No.: US 2013/0112453 A1
(43) Pub. Date: May 9, 2013

(54) STRUCTURAL IMPROVEMENT OF A FILTER CASING

(71) Applicant: Shang-Tsan LIEN, New Taipei City (TW)

(72) Inventor: Shang-Tsan LIEN, New Taipei City (TW)

(73) Assignee: YUNPEN ELECTRONIC CO., LTD., New Taipei City (TW)

(21) Appl. No.: 13/292,396

(22) Filed: Nov. 9, 2011

(51) Int. Cl. H05K 5/00

(52) U.S. Cl. 174/50

(57) ABSTRACT

The present invention relates to a structural improvement of a filter casing comprising a base and a cover. The base contains an accommodating space to install a filter module, wherein two edges of the accommodating space are respectively integrated with at least two or more fasteners that extend by leaning inwards, making the cover assemble and cover up the opening of the accommodating space of the base, while two edges of the cover are integrated with at least two or more locking holes used to engage and fix the fasteners on the two edges of the accommodating space correspondingly, thus accelerating the assembly of components in a filter, reducing the assembly procedures and time and enhancing the quality and production of filters.

### BACKGROUND OF THE INVENTION

1. Field of the Invention

The present invention relates to a structural improvement of a filtercasing, particularly to a filter casing that allows quick assembly of the base and cover to increase production capabilities of filters by assembling and fixing fasteners on two edges of the opening of the accommodating space of the base into locking holes of the cover, so as to accelerate fabrication of filters.

2. Description of the Related Art

With high performance, high efficiency and multipurpose application of electronic and electrical products, many powerful electronic components are used to promote practical functions of these products. As a result, static electricity, noise and electromagnetic waves go in all directions when electronic and electrical products are working, producing negative effect on quality of these products. For this reason, some professionals install filters in electronic and electrical products to filter out electrostatic, noise or electromagnetic interference generated in the process of working. Usually, various kinds of filter coils, capacitors, resistors or other components of filters are installed in metal casings, so that various kinds of electrostatic, noise Or electromagnetic interference can be released outwardly through earthing after various kinds of noise are received. This helps improve the quality of electronic and electrical products. For a filter A in conventional use, however, various components A1 including the filter coil A11, the capacitor A12 and resistors, etc. shall be installed in the internal space A30 of the screening iron casing A3 and a cover A4 is placed above the internal space A30 of the screening iron casing A3 in the process of assembly, so as to solder and assemble the joint part of the screening iron casing A3 and cover A4, and the screening iron casing A3 and the cover A4 will be soldered together, as shown in FIGS. 5 and 6. Yet in the soldering process, the cover A4 is liable to slanting and deflection from the screening iron casing A3 due to effect of soldering operations, making it difficult to put the cover A4 onto the screening iron casing properly. This will cause considerable difficulty in soldering and packaging of the screening iron casing A1 Besides, high temperature generated in the process of soldering may also cause damage or failure of the filter components A1 inside the screening iron casing A3 indirectly, degrading the filtering quality.

Thus, how to overcome the problems and difficulties in aligning the upper and lower covers of filters and eliminating the negative impact on filtering quality in the process of fabrication and soldering operations is what the firms engaged in this field need urgently to research and improve.

### SUMMARY OF THE INVENTION

In view of the aforesaid problems and disadvantages, the inventor has collected related information, conducted assessments and taken considerations in many aspects, and based on his own experience of many years in this field, has finally invented the structural improvement of a filter casing that allows quick and accurate alignment for soldering and packaging to increase the quality and production capacity of filters.

The primary object of the present invention is to include a base and a cover in a filter, wherein the base contains an accommodating space for a filter module to be installed, and two edges of an opening of the accommodating space are integrated with at least two or more fasteners to make the cover assemble and cover up the opening of the accommodating space of the base, while two edges of the cover are integrated with at least two or more locking holes used to engage and fix the fasteners on the two edges of the accommodating space correspondingly, thus accelerating the assembly of components in a filter, reducing the assembly procedures and time and enhancing the quality and production of filters.

### BRIEF DESCRIPTION OF THE DRAWINGS

FIG. 1 is a perspective view according to the present invention.

FIG. 2 is an exploded perspective view according to the present invention.

FIG. 3 is a side sectional view according to the present invention,

FIG. 4 is a perspective view following fabrication according to the present invention.

FIG. 5 is a partial exploded perspective view of a conventional filter.

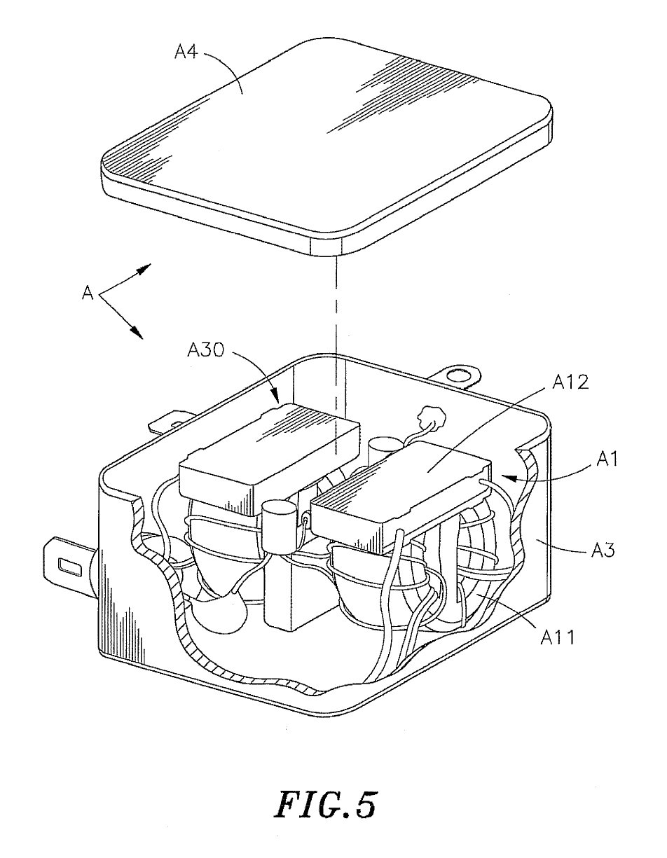

FIG. 6 is a side view of the conventional filter.

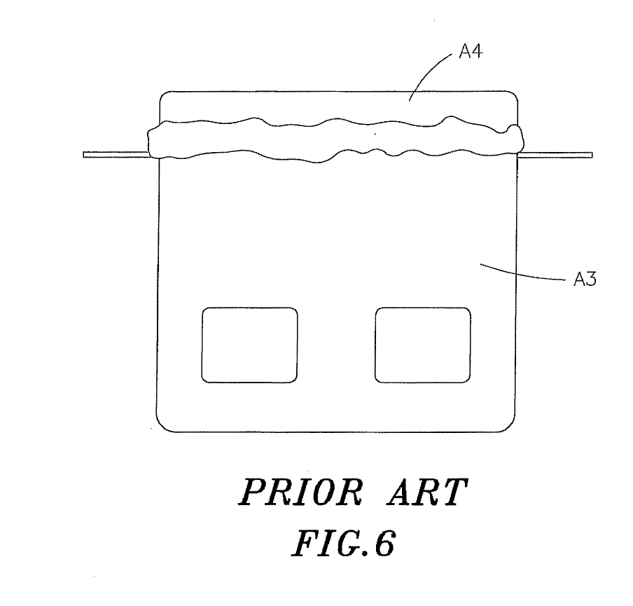

### DETAILED DESCRIPTION OF THE PREFERRED EMBODIMENT

To achieve the aforesaid objects and functions as well as the techniques adopted in the present invention and its fabrication, examples of the preferred embodiments of the present invention are given below to illustrate features and functions of the present invention in detail by referring to the accompanying drawings.

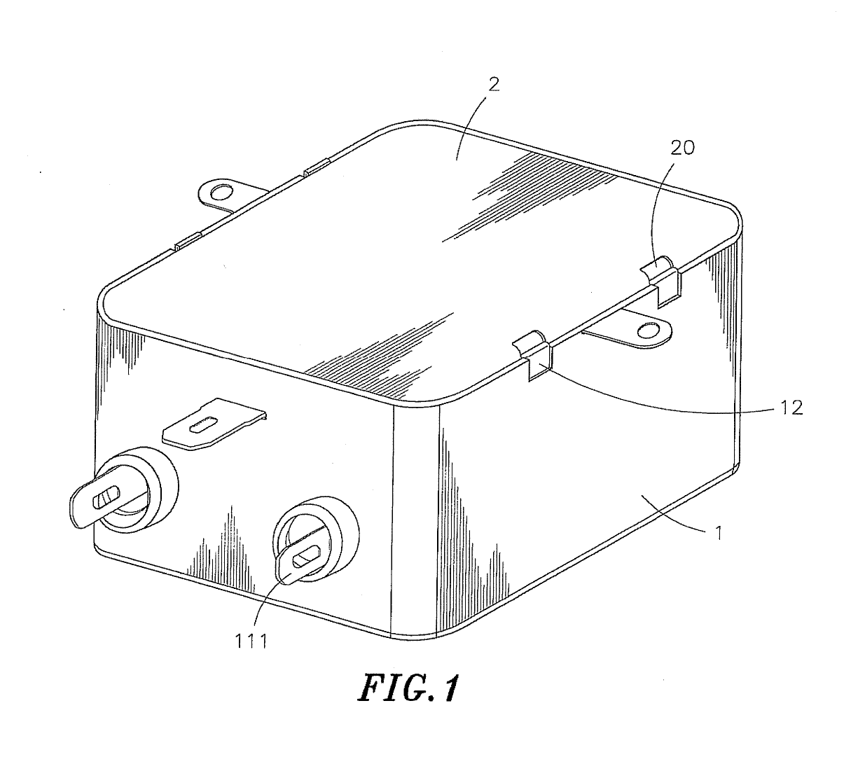

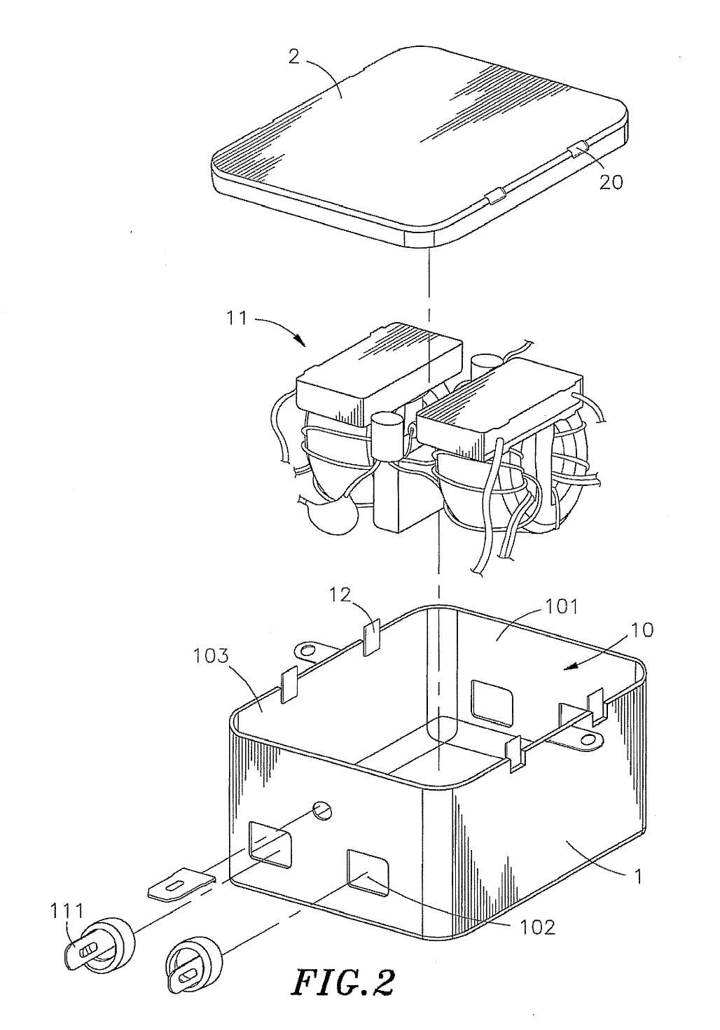

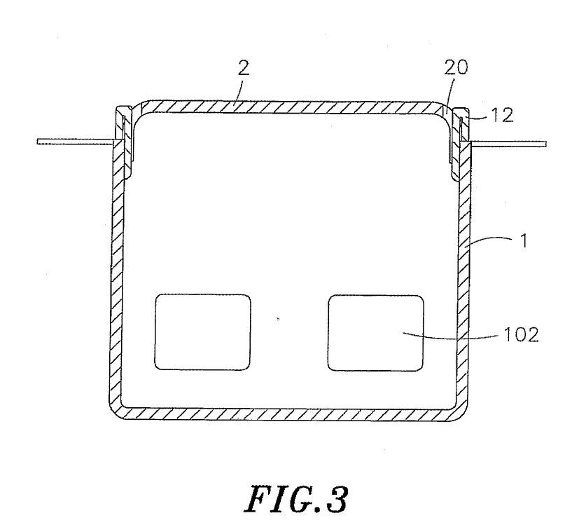

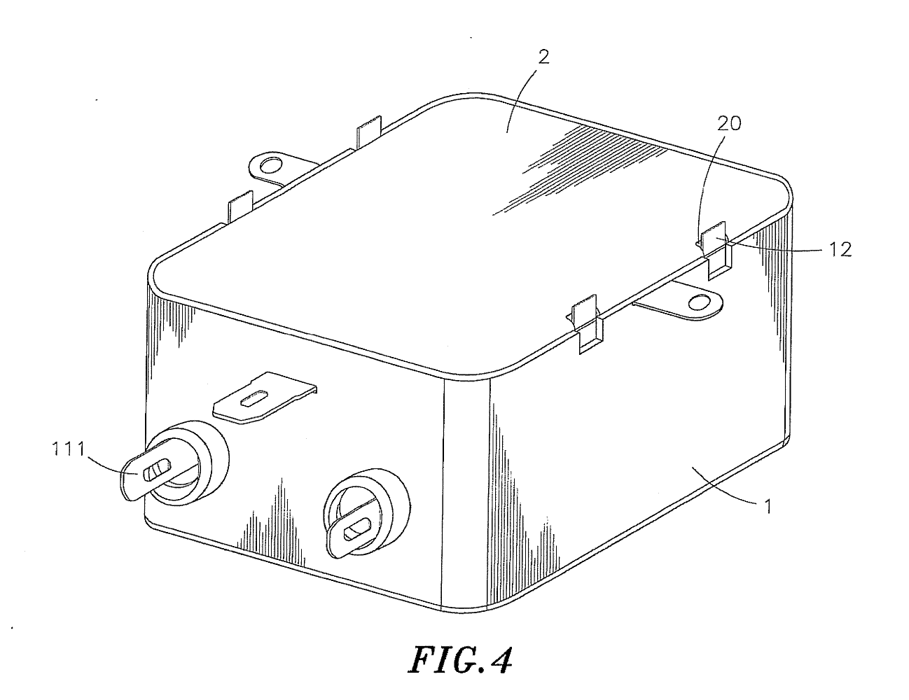

Refer to FIGS. 1, 2, 3 and 4, which are a perspective view, an exploded perspective view, a side sectional view and a perspective view following fabrication according to the present invention respectively. As shown clearly in these figures, a filter casing disclosed in the present invention includes a base 1 and a cover 2.

The base 1 has an accommodating space 10 where a filter module 11 is installed. The filter module 11 has contacts 111 going through slot holes 102 on side walls 101 of the accommodating space 10 and going out of the base 1. The accommodating space 10 includes an opening 103 whose two opposite edges are integrated with at least two or more fasteners 12 respectively, and the fasteners 12 lean inwards respectively and have elastic force that generated from elastic deformation.

The two opposite edges of the cover 2 are integrated with at least two or more locking holes 20 respectively.

For assembly of the aforesaid components, put the cover 2 onto the opening 103 of the accommodating space 10 of the base 1, and assemble, lock and fix the fasteners 12 on two opposite edges of the opening 103 of the accommodating space 10 into the locking holes 20 of the cover 2 respectively, so that the cover 2 can be placed onto the opening 103 to cover up the accommodating space. After the fasteners 12 are fixed into the locking holes 20, the remaining parts of the fasteners 12 that go beyond the locking holes 20 are budded outwards to lean toward the external sides of the cover 2, and fabrication of the filter as disclosed in the present invention is completed.

In the filter of the present invention, the base 1 and the cover 2 can be assembled and integrated very quickly by putting the cover 2 onto the accommodating space 10 of the base 1 and fixing the fasteners 12 on two opposite edges of the accommodating space 10 into the locking holes of the cover 2, without the need to carry out trivial steps and procedures of aligning and soldering, etc. Besides, it can also prevent the filter module 11 from being damaged or breaking down due to high soldering temperature, thus reducing the probability of damage to filter components, resistors, capacitors or other components and maintaining good filtering effectiveness of the filter module 11. Therefore, this assembly method is effective in reducing the time needed for assembly and integration of the base 1 and cover 2, increasing the output of filters, improving the yield rate and lowering the manufacture cost.

The filter module 11 installed in the accommodating space 10 of the base 1 may include filter components, resistors, capacitors or other related electronic components, all of which are used to filter signals and eliminate noise, electromagnetic or electrostatic interference, while the contacts 111 of the filter module 11 go through the slot holes 102 on the side walls 101 of the accommodating space 10 respectively and extend beyond the base 1 respectively, so as to connect to circuit layouts or circuit boards electrically for use in electronic or electrical products.

Thus, the above descriptions are given only to illustrate a preferred embodiment of the present invention and shall not be construed as limiting the appended patent claims of the present invention. The structure of the filter casing in the present invention is designed to contain the filter module 11 in the accommodating space 10 of the base 1 and establish two or more fasteners 12 respectively on the two edges of the opening 103 of the accommodating space 10, so that the base 1 and the cover 2 can be assembled quickly by putting the cover 2 onto the accommodating space 10 and fixing the fasteners 12 into the multiple locking holes 20 on the cover 2 and making the remaining parts of the fasteners 12 be buckled, without the need to carry out soldering procedures. This allows assembly of the base 1 with the cover 2 to be completed very quickly and helps shorten the manufacture process and increase the output, thus achieving the purposes of reducing the manufacture costs and improve the filtering performance of filters. It is hereby stated that all fabrications and devices that can achieve the aforesaid purposes shall be covered by the present invention and that all modifications and equivalent structural changes made without departing from the spirit and art of the present invention shall be included in the appended patent claims of the present invention.

Thus, the present invention mainly deals with design of a filter casing, in which two or more fasteners are established on two edges of an opening of an accommodating space of a base for assembly and fastening into multiple locking holes on two edges of a cover, so as to quickly assemble and produce a filter by fastening the cover onto the base through the fasteners and locking holes, without the need to perform soldering processing that may affect functions of the filter module due to high temperature. This helps maintain the advantage of the filter module in filtering effectiveness, increase the output and yield rate of filters and reduce the manufacture costs, However, the above descriptions are given only to illustrate one preferred embodiment of the present invention and shall not be construed as limiting the appended patent claims of the present invention. It is hereby stated that all modifications and equivalent structural changes made without departing from the spirit and art of the present invention shall be included in the appended patent claims of the present invention.

In summary, the structural improvement of a filter casing as disclosed in the present invention can achieve its functions and objects when applied practically. Therefore, the present invention is really an excellent one with practical applicability and can satisfy the terms and conditions for patentability of a utility model. While the application of patent is filed pursuant to applicable laws, your early approval will be highly appreciated so as to guarantee benefits and rights of the inventor who has worked hard at this invention.

What the invention claimed is:

1. A filter casing, comprising a base and a cover, wherein:
the base has an accommodating space for installing a filter module, and two edges of the opening of the accommodating space are integrated with at least two or more fasteners respectively;
the cover is installed and placed onto the opening of the accommodating space of the base, and two edges of the cover are integrated with at least two or more locking holes to engage and fix fasteners on the two edges of the base.

2. The filter casing according to claim 1, wherein the two edges of the opening of the accommodating space of the base are respectively integrated with at least two or more fasteners that extend inwards and have elasticity.

3. The filter casing according to claim 1, wherein the two edges of the accommodating space of the base are respectively integrated with at least two or more fasteners with elasticity, while the two edges of the cover are respectively integrated with at least two or more locking holes used to engage and fix the fasteners correspondingly.

4. The filter casing according to claim 1, wherein the size of the opening of the accommodating space of the base is wider than that of the cover, so that the cover can be put into the opening to cover the accommodating space.
